(19) United States
(12) Patent Application Publication
(10) Pub. No.: US 2025/0078887 A1
(43) Pub. Date: Mar. 6, 2025

(54) MEMORY

(71) Applicant: CXMT CORPORATION, Hefei (CN)

(72) Inventors: Yifei LUO, Hefei (CN); Hangtian BA, Hefei (CN)

(21) Appl. No.: 18/949,989

(22) Filed: Nov. 16, 2024

Related U.S. Application Data
(63) Continuation of application No. PCT/CN2023/074398, filed on Feb. 3, 2023.

(30) Foreign Application Priority Data
Nov. 4, 2022 (CN) 202211376117.0

(51) Int. Cl. G11C 7/12

(52) U.S. Cl. CPC G11C 7/12

(57) ABSTRACT

A memory includes: a first-stage amplifier circuit, connected to a bit line and a complementary bit line, and configured to amplify a voltage difference between the bit line and the complementary bit line; a second-stage amplifier circuit, connected to a local data line and a complementary local data line, further connected to a global data line and a complementary global data line, amplifying a voltage difference between the local data line and the complementary local data line after the local data line is connected to the bit line and the complementary local data line is connected to the complementary bit line, and generating a voltage difference between the global data line and the complementary global data line; and a driving circuit, connected to the local data line and the complementary local data line, and amplifying the voltage difference between the local data line and the complementary local data line.

### CROSS-REFERENCE TO RELATED APPLICATION(S)

This application is a continuation of International Patent Application No. PCT/CN2023/074398, filed on Feb. 3, 2023, which claims the benefit of Chinese Patent Application No. 202211376117.0, titled “MEMORY”, filed with the China National Intellectual Property Administration (CNIPA) on Nov. 4, 2022, the disclosures of which are incorporated herein by reference in their entireties.

### TECHNICAL FIELD

The present disclosure relates to but is not limited to a memory.

### BACKGROUND

With the popularization of electronic devices such as mobile phones, tablet computers, and personal computers, semiconductor memory technologies are also rapidly developed.

Multiple stages of amplifier circuits are disposed in a dynamic random access memory (DRAM). A voltage difference is amplified by the multiple stages of amplifier circuits to read data from or write data into a storage cell. Therefore, performance of the memory can be improved by improving the multiple stages of amplifier circuits.

### SUMMARY

The present disclosure provides a memory, including:
a first-stage amplifier circuit, connected to a bit line and a complementary bit line, and configured to amplify a voltage difference between the bit line and the complementary bit line;
a second-stage amplifier circuit, connected to a local data line and a complementary local data line, further connected to a global data line and a complementary global data line, amplifying a voltage difference between the local data line and the complementary local data line after the local data line is connected to the bit line and the complementary local data line is connected to the complementary bit line, and generating a voltage difference between the global data line and the complementary global data line; and
a driving circuit, connected to the local data line and the complementary local data line, and amplifying the voltage difference between the local data line and the complementary local data line.

In some embodiments, the memory further includes:
an equalizer circuit, connected to the local data line and the complementary local data line, and charging voltages on the local data line and the complementary local data line to a precharge voltage before the local data line is connected to the bit line and the complementary local data line is connected to the complementary bit line.

The driving circuit is configured to amplify the voltage difference between the local data line and the complementary local data line after the voltages on the local data line and the complementary local data line are charged to the precharge voltage.

In some embodiments, a start moment at which the driving circuit amplifies the voltage difference between the local data line and the complementary local data line is earlier than a start moment at which the second-stage amplifier circuit amplifies the voltage difference between the local data line and the complementary local data line.

In some embodiments, a first start moment is in a first value range when a first time interval is in a first time range.

The first start moment is in a second value range when the first time interval is in a second time range.

The first time interval is a time interval between adjacent row addressing and column addressing of the memory. The first start moment is a start moment at which the driving circuit starts to amplify the voltage difference between the local data line and the complementary local data line.

An upper limit value of the first time range is less than or equal to a lower limit value of the second time range. An upper limit value of the first value range is greater than or equal to a lower limit value of the second value range.

In some embodiments, the driving circuit is configured to:
amplify the voltage difference between the local data line and the complementary local data line by driving a voltage on the local data line and/or a voltage on the complementary local data line upward.

A driving capability of driving the local data line upward is negatively correlated with the voltage on the complementary local data line. A driving capability of driving the complementary local data line upward is negatively correlated with the voltage on the local data line.

In some embodiments, the driving circuit includes:
a switch unit, connected to a first driving unit and a second driving unit, controlling connection or disconnection between the first driving unit and a first power supply terminal under the control of a first control signal, and controlling connection or disconnection between the second driving unit and the first power supply terminal under the control of the first control signal, the first power supply terminal providing a power voltage;
the first driving unit, connected to the local data line and the complementary local data line, and driving the voltage on the local data line upward based on the voltage on the complementary local data line when the first driving unit is connected to the first power supply terminal; and
the second driving unit, connected to the local data line and the complementary local data line, and driving the voltage on the complementary local data line upward based on the voltage on the local data line when the second driving unit is connected to the first power supply terminal.

In some embodiments, a driving capability of the first driving unit in driving the local data line is negatively correlated with the voltage on the complementary local data line.

A driving capability of the second driving unit in driving the complementary local data line is negatively correlated with the voltage on the local data line.

In some embodiments, the first driving unit includes:
a first P-type transistor, a source being connected to the switch unit, a drain being connected to the local data line, and a gate being connected to the complementary local data line.

The second driving unit includes:
a second P-type transistor, a source being connected to the switch unit, a drain being connected to the complementary local data line, and a gate being connected to the local data line.

In some embodiments, the switch unit includes:
a third P-type transistor, a source being connected to the first power supply terminal, a drain being connected to the source of the first P-type transistor, the drain being further connected to the source of the second P-type transistor, and a gate receiving the first control signal.

In some embodiments, the driving circuit further includes:
a first control circuit, a first output terminal being connected to a control terminal of the switch unit, a second output terminal being connected to a control terminal of the second-stage amplifier circuit, and a first input terminal receiving a mode signal and a second input terminal receiving a reference signal to generate the first control signal based on the mode signal and the reference signal and generate a second control signal based on the reference signal.

A start moment at which the first control signal is in a valid state is earlier than a start moment at which the second control signal is in a valid state. The second-stage amplifier circuit is controlled by the second control signal to amplify the voltage difference between the local data line and the complementary local data line.

In some embodiments, the start moment at which the first control signal is in the valid state is later than an end moment at which an equalization control signal is in a valid state. The voltages on the local data line and the complementary local data line are charged to a precharge voltage when the equalization control signal is in the valid state.

In some embodiments, the control circuit is configured to:
determine a time step between the reference signal and the first control signal based on the mode signal; and process the reference signal based on the time step to generate the first control signal.

In some embodiments, the mode signal is determined based on any one or more parameters of a first time interval, a process angle of the memory, a temperature of the memory, and an operating voltage of the memory.

The first time interval is a time interval between adjacent row addressing and column addressing of the memory.

In some embodiments, the reference signal is a column selection signal. The column selection signal is configured to control connection or disconnection between the bit line and the local data line, and is further configured to control connection or disconnection between the complementary bit line and the complementary local data line.

In some embodiments, the memory further includes:
a second control circuit, connected to the bit line and the complementary bit line, further connected to the local data line and the complementary local data line, and configured to receive a column selection signal, control connection or disconnection between the bit line and the local data line under the control of the column selection signal, and control connection or disconnection between the complementary bit line and the complementary local data line under the control of the column selection signal.

In some embodiments, the memory further includes:
a third-stage amplifier circuit, connected to the global data line and the complementary global data line, and configured to amplify the voltage difference between the global data line and the complementary global data line.

The memory provided in the present disclosure includes a first-stage amplifier circuit, a second-stage amplifier circuit, and a driving circuit. The first-stage amplifier circuit is connected to a bit line and a complementary bit line. A voltage difference between the bit line and the complementary bit line is amplified by the first-stage amplifier circuit. Both the driving circuit and the second-stage amplifier circuit are connected to a local data line and a complementary local data line. The second-stage amplifier circuit is further connected to a global data line and a complementary global data line. A voltage difference between the local data line and the complementary local data line is amplified by the second-stage amplifier circuit after the voltage difference is generated between the local data line and the complementary local data line, and a voltage difference is generated between the global data line and the complementary global data line. The driving circuit is also configured to amplify the voltage difference between the local data line and the complementary local data line. Therefore, an impact of coupling capacitors on voltages on local data lines is compensated for, a time for amplifying the voltage difference between the local data line and the complementary local data line can be shortened, and performance of a timing parameter of the memory can be improved.

### BRIEF DESCRIPTION OF DRAWINGS

The accompanying drawings herein, which are incorporated in and constitute a part of the specification, illustrate embodiments conforming to the present disclosure, and are used together with the specification to explain the principles of the present disclosure.

FIG. 1 is a schematic diagram of a circuit of a memory;

FIG. 2 is a wiring diagram of a local data line in a memory;

FIG. 3 is a schematic diagram of a principle of an impact of coupling capacitors on voltages on local data lines in a memory;

FIG. 4 is a diagram of an operating principle when there is an impact of coupling capacitors on voltages on local data lines in a memory;

FIG. 5 is a schematic diagram of a circuit of a memory according to an embodiment of

the present disclosure;

FIG. 6 is an operational timing diagram of a memory according to an embodiment of the present disclosure; and

FIG. 7 is a diagram of an operating principle of a memory according to an embodiment of the present disclosure.

### REFERENCE NUMERALS

100. first-stage amplifier circuit; 200. second-stage amplifier circuit; 300. third-stage amplifier circuit; 400. second control circuit; 500. equalizer circuit; 600. driving circuit; 700. first control circuit; 610. first driving unit; 620. second driving unit; 630. switch unit; BL. bit line; BLB. complementary bit line; LIO. local data line; LIOB. complementary local data line; GIO. global data line; GIOB. complementary global data line; M1. first transistor; M2. second transistor; CSL. column selection signal; VintLP. second power supply terminal; RdEnN. first control signal; RdEn. second control signal; CTRLPin. mode signal; RdEnPre. reference signal; P1. first P-type transistor; P2. second P-type transistor; P3. third P-type transistor; and EQLOB. equalization control signal.

The foregoing accompanying drawings already show clear embodiments of the present disclosure, which are described in more detail below. These accompanying drawings and text descriptions are not intended to limit the scope of the concept of the present disclosure in any manner, but to describe the concept of the present disclosure for a person skilled in the art with reference to specific embodiments.

### DESCRIPTION OF EMBODIMENTS

Example embodiments are described herein in detail, and examples thereof are shown in the accompanying drawings. When the following descriptions relate to the accompanying drawings, unless otherwise indicated, the same numbers in different accompanying drawings represent the same or similar elements. Implementations described in the following example embodiments do not represent all implementations consistent with the present disclosure. On the contrary, they are merely examples of apparatuses and methods that are consistent with some aspects of the present disclosure as detailed in the appended claims.

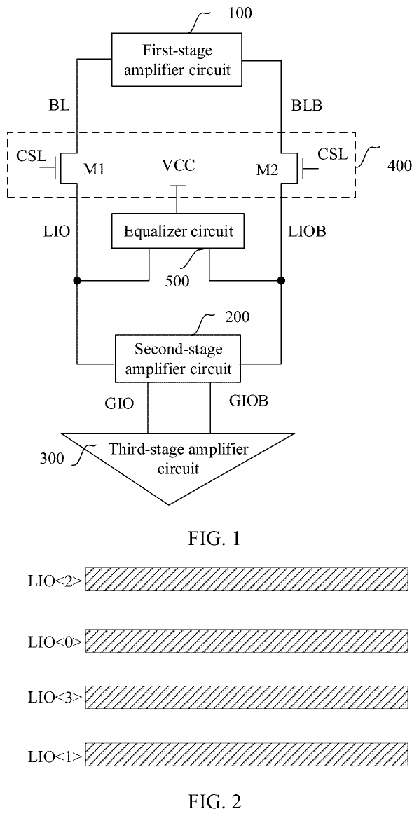

As shown in FIG. 1, a memory includes a first-stage amplifier circuit 100, a second-stage amplifier circuit 200, a third-stage amplifier circuit 300, a second control circuit 400, and an equalizer circuit 500. The first-stage amplifier circuit 100 is connected to a bit line BL and a complementary bit line BLB. The first-stage amplifier circuit 100 is configured to amplify a voltage difference between the bit line BL and the complementary bit line BLB. The second-stage amplifier circuit 200 is connected to a local data line LIO and a complementary local data line LIOB. The second-stage amplifier circuit 200 is further connected to a global data line GIO and a complementary global data line GIOB. The second-stage amplifier circuit 200 is configured to amplify a voltage difference between the local data line LIO and the complementary local data line LIOB, and generate a voltage difference between the global data line GIO and the complementary global data line GIOB. The third-stage amplifier circuit 300 is configured to amplify the voltage difference between the global data line GIO and the complementary global data line GIOB.

The second control circuit 400 is connected to the bit line BL and the complementary bit line BLB. The second control circuit 400 is connected to the local data line LIO and the complementary local data line LIOB. The second control circuit 400 is configured to control connection or disconnection between the bit line BL and the local data line LIO. The second control circuit 400 is further configured to control connection or disconnection between the complementary bit line BLB and the complementary local data line LIOB.

The equalizer circuit 500 is connected to the local data line LIO and the complementary local data line LIOB. The equalizer circuit 500 is configured to charge both of the local data line LIO and the complementary local data line LIOB to a precharge voltage VCC before the bit line BL is connected to the local data line LIO and the complementary bit line BLB is connected to the complementary local data line LIOB.

Charge sharing is performed between a storage cell and the bit line BL before the bit line BL is connected to the local data line LIO and the complementary bit line BLB is connected to the complementary local data line LIOB. A small voltage difference is generated between the bit line BL and the complementary bit line BLB. The small voltage difference between the bit line BL and the complementary bit line BLB is amplified by the first-stage amplifier circuit 100.

The voltage difference is generated between the local data line LIO and the complementary local data line LIOB by the bit line BL and the complementary bit line BLB after the bit line BL is connected to the local data line LIO and the complementary bit line BLB is connected to the complementary local data line LIOB. Then, the voltage difference between the local data line LIO and the complementary local data line LIOB is amplified by the second-stage amplifier circuit 200, so that data is transmitted from the bit line BL and the complementary bit line BLB to the local data line LIO and the complementary local data line LIOB.

FIG. 2 is a wiring diagram of some local data lines LIO in a memory. Multiple local data lines LIO are sequentially arranged. A coupling capacitor exists between two local data lines LIO. Voltages on the local data lines LIO are affected when voltage jump occurs on the coupling capacitor.

For example, four local data lines LIO in FIG. 2 are sequentially marked from top to bottom as a local data line LIO<2>, a local data line LIO<0>, a local data line LIO<3>, and a local data line LIO<1>. A coupling capacitor exists between the local data line LIO<2> and the local data line LIO<3>.

As shown in FIG. 3, voltages on the local data line LIO<2> and the local data line LIO<3> are reduced from the precharge voltage VCC to a voltage corresponding to data “0” due to transmission of the data “0”. However, a voltage on the local data line LIO<0> is still close to the precharge voltage VCC when data “1” is transmitted. The voltage on the local data line LIO<0> is affected and reduced by the coupling capacitor between the local data line LIO<2> and the local data line LIO<3> because voltage jump occurs on the local data line LIO<2> and the local data line LIO<3>.

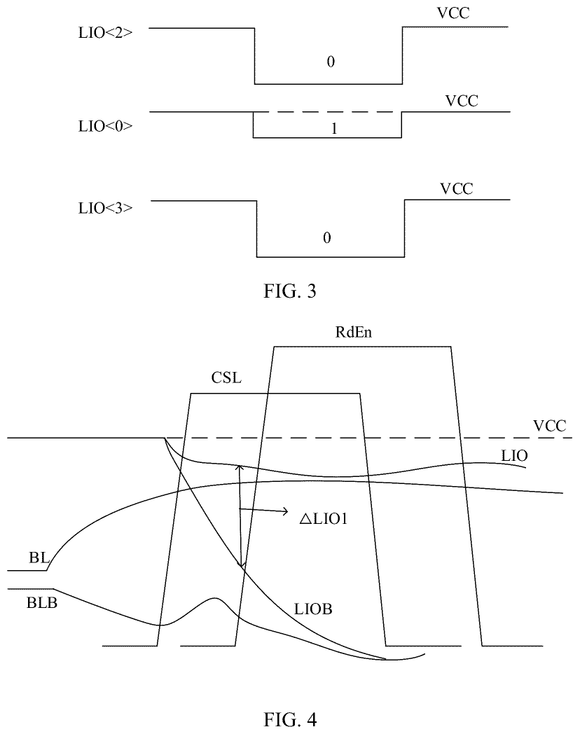

As shown in FIG. 4, a value of a voltage difference ΔLIO1 is small when a voltage difference between the local data line LIO<0> and a complementary local data line LIOB<0> is amplified by the second-stage amplifier circuit. A longer time is required by the second-stage amplifier circuit 200 to amplify the voltage difference between the local data line LIO<0> and the complementary local data line LIOB<0> to a preset value. A timing parameter tCCD of the memory refers to a time interval between a current column address strobe and a next column address strobe. The timing parameter tCCD of the memory is caused to be poorer by the longer time required by the second-stage amplifier circuit 200 to amplify the voltage difference between the local data line LIO and the complementary local data line LIOB.

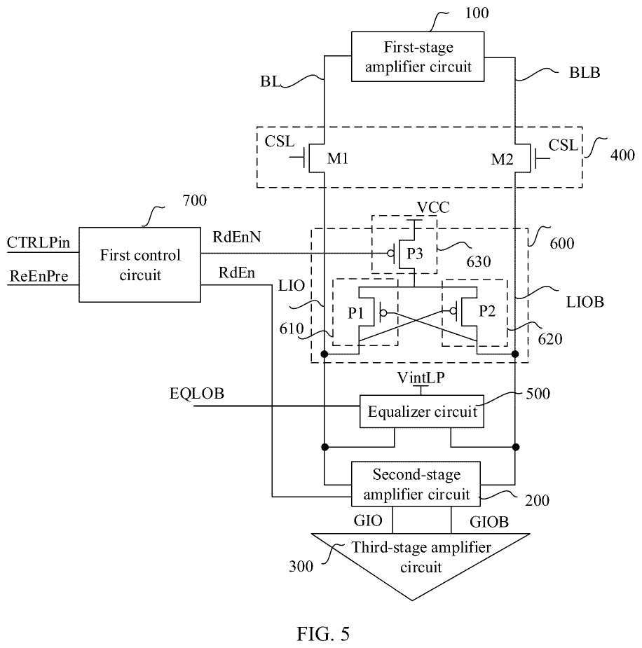

As shown in FIG. 5, an embodiment of the present disclosure provides a memory, including a first-stage amplifier circuit 100, a second-stage amplifier circuit 200, and a driving circuit 600.

The first-stage amplifier circuit 100 is connected to a bit line BL and a complementary bit line BLB. The second-stage amplifier circuit 200 is connected to a local data line LIO and a complementary local data line LIOB. The second-stage amplifier circuit 200 is further connected to a global data line GIO and a complementary global data line GIOB. The driving circuit 600 is connected to the local data line LIO and the complementary local data line LIOB.

Charge sharing is performed between a storage cell and the bit line BL after the local data line LIO is disconnected from the bit line BL and the complementary local data line LIOB is disconnected from the complementary bit line BLB. In this case, a small voltage difference is generated between the bit line BL and the complementary bit line BLB. The first-stage amplifier circuit 100 is configured to amplify the small voltage difference between the bit line BL and the complementary bit line BLB.

The local data line LIO is driven by the bit line BL and the complementary local data line LIOB is driven by the complementary bit line BLB after the local data line LIO is connected to the bit line BL and the complementary local data line LIOB is connected to the complementary bit line BLB, to generate a voltage difference between the local data line LIO and the complementary local data line LIOB. The second-stage amplifier circuit 200 amplifies the voltage difference between the local data line LIO and the complementary local data line LIOB, and generates a voltage difference between the global data line GIO and the complementary global data line GIOB. The voltage difference between the local data line LIO and the complementary local data line LIOB is further amplified by the driving circuit 600 after the voltage difference is generated between the local data line LIO and the complementary local data line LIOB.

In the foregoing technical solution, the driving circuit 600 connected to the local data line LIO and the complementary local data line LIOB is disposed. The voltage difference between the local data line LIO and the complementary local data line LIOB is amplified by the second-stage amplifier circuit 200 after the voltage difference is generated between the local data line LIO and the complementary local data line LIOB. The driving circuit 600 is also configured to amplify the voltage difference between the local data line LIO and the complementary local data line LIOB. Therefore, an impact of coupling capacitors on voltages on the local data lines LIO is compensated for, a time for amplifying the voltage difference between the local data line LIO and the complementary local data line LIOB can be shortened, and a timing parameter tCCD of the memory can be improved.

In some embodiments, continuing to refer to FIG. 5, the memory further includes an equalizer circuit 500. The equalizer circuit 500 is connected to the local data line LIO and the complementary local data line LIOB. Voltages on the local data line LIO and the complementary local data line LIOB are charged to a precharge voltage by the equalizer circuit 500 before the local data line LIO is connected to the bit line BL and the complementary local data line LIOB is connected to the complementary bit line BLB.

The bit line BL and the local data line LIO are controlled to be connected and the complementary bit line BLB and the complementary local data line LIOB are controlled to be connected after the voltages on the local data line LIO and the complementary local data line LIOB are charged to the precharge voltage by the equalizer circuit 500. The voltage difference between the local data line LIO and the complementary local data line LIOB is generated by the bit line BL and the complementary bit line BLB. The voltage difference between the local data line LIO and the complementary local data line LIOB is amplified by the driving circuit 600. The voltage difference between the local data line LIO and the complementary local data line LIOB is also amplified by the second-stage amplifier circuit 200.

In some embodiments, continuing to refer to FIG. 5, the equalizer circuit 500 is connected to a second power supply terminal. A voltage VintLP on the second power supply terminal is adjustable, so that the precharge voltage is also adjustable. The voltage VintLP provided by the second power supply terminal may be adjusted based on the timing parameter of the memory, to adjust the precharge voltage for the local data line LIO and the complementary local data line LIOB.

In some embodiments, the driving circuit 600 is connected and enters a waiting state after the local data line LIO and the complementary local data line LIOB are charged to the precharge voltage and before the bit line BL is connected to the local data line LIO and the complementary bit line BLB is connected to the complementary local data line LIOB. The voltage difference is generated between the local data line LIO and the complementary local data line LIOB by the bit line BL and the complementary bit line BLB after the bit line BL is connected to the local data line LIO and the complementary bit line BLB is connected to the complementary local data line LIOB. The voltage difference between the local data line LIO and the complementary local data line LIOB is amplified by the driving circuit 600.

In some embodiments, the driving circuit 600 is connected after the bit line BL is connected to the local data line LIO and the complementary bit line BLB is connected to the complementary local data line LIOB. The voltage difference between the local data line LIO and the complementary local data line LIOB is directly amplified by the driving circuit 600, and the driving circuit 600 does not need to enter the waiting state.

In the foregoing technical solution, the driving circuit 600 and the second-stage amplifier circuit 200 are controlled after the voltages on the local data line LIO and the complementary local data line LIOB are charged to the precharge voltage, to amplify the voltage difference between the local data line LIO and the complementary local data line LIOB, to implement accurate data transmission between the bit line BL and the local data line LIO and between the complementary bit line BLB and the complementary local data line LIOB.

In some embodiments, continuing to refer to FIG. 5, the memory further includes a second control circuit 400. The second control circuit 400 is connected to the bit line BL and the complementary bit line BLB. The second control circuit 400 is further connected to the local data line LIO and the complementary local data line LIOB. The second control circuit 400 is configured to receive a column selection signal CSL. Connection or disconnection between the bit line BL and the local data line LIO and connection or disconnection between the complementary bit line BLB and the complementary local data line LIOB are controlled by the second control circuit 400 under the control of the column selection signal CSL.

In some embodiments, continuing to refer to FIG. 5, the second control circuit 400 includes a first transistor M1 and a second transistor M2. A source or a drain of the first transistor M1 is connected to the bit line BL. The drain or the source of the first transistor M1 is connected to the local data line LIO. A gate of the first transistor M1 is connected to a column selection line to receive the column selection signal CSL. A source or a drain of the second transistor M2 is connected to the complementary bit line BLB. The drain or the source of the second transistor M2 is connected to the complementary local data line LIOB. A gate of the second transistor M2 is connected to the column selection line to receive the column selection signal CSL.

The first transistor M1 and the second transistor M2 are turned on or off under the control of the column selection signal CSL, to control connection or disconnection between the bit line BL and the local data line LIO and connection or disconnection between the complementary bit line BLB and the complementary local data line LIOB.

In some embodiments, the first transistor M1 and the second transistor M2 are N-type transistors. The first transistor M1 and the second transistor M2 are controlled to be turned on when the column selection signal CSL is at a high level.

In some embodiments, continuing to refer to FIG. 5, the memory further includes a third-stage amplifier circuit 300. The third-stage amplifier circuit 300 is connected to the global data line GIO and the complementary global data line GIOB. The third-stage amplifier circuit 300 is configured to amplify the voltage difference between the global data line GIO and the complementary global data line GIOB.

In some embodiments, a start moment at which the driving circuit 600 amplifies the voltage difference between the local data line LIO and the complementary local data line LIOB is earlier than a start moment at which the second-stage amplifier circuit 200 amplifies the voltage difference between the local data line LIO and the complementary local data line LIOB. Through such a disposition, the voltage difference between the local data line LIO and the complementary local data line LIOB is first amplified by the driving circuit 600 after the voltage difference is generated between the local data line LIO and the complementary local data line LIOB by the bit line BL and the complementary bit line BLB, to compensate for the impact of the coupling capacitors on the voltages on the local data lines LIO. Then, the second-stage amplifier circuit 200 and the driving circuit 600 together amplify the voltage difference between the local data line LIO and the complementary local data line LIOB, and generate the voltage difference between the global data line GIO and the complementary global data line GIOB. Therefore, a time for amplifying the voltage difference between the local data line LIO and the complementary local data line LIOB by the second-stage amplifier circuit 200 is shortened, and performance of the timing parameter tCCD of the memory is improved.

In some embodiments, a first time interval is a time interval tRCD between adjacent row addressing and column addressing of the memory, that is, a time interval between adjacent active command and read command or a time interval between adjacent active command and write command. That is, the first time interval is a time interval from enabling a word line to enabling the column selection line.

A first start moment is a start moment at which the driving circuit 600 amplifies the voltage difference between the local data line LIO and the complementary local data line LIOB.

The first start moment is in a first value range when the first time interval is in a first time range. The first start moment is in a second value range when the first time interval is in a second time range. An upper limit value of the first time range is less than or equal to a lower limit value of the second time range. An upper limit value of the first value range is greater than or equal to a lower limit value of the second value range.

A shorter first time interval indicates a later start moment at which the driving circuit 600 amplifies the voltage difference between the local data line LIO and the complementary local data line LIOB. If the first time interval is short, the voltage difference between the bit line BL and the complementary bit line BLB is smaller when the bit line BL is connected to the local data line LIO and the complementary bit line BLB is connected to the complementary local data line LIOB, and noise is more easily introduced to the bit line BL and the complementary bit line BLB by the local data line LIO and the complementary local data line LIOB. The start moment at which the driving circuit 600 amplifies the voltage difference between the local data line LIO and the complementary local data line LIOB is delayed, to reduce an impact of the local data line LIO and the complementary local data line LIOB on the bit line BL and the complementary bit line BLB, thereby reducing noise introduction.

In some embodiments, the first start moment may be further adjusted based on any one or more parameters of a process angle of the memory, a temperature of the memory, and an operating voltage of the memory, to reduce the noise introduced to the bit line BL and the complementary bit line BLB. Multiple tests may be performed on the memory to determine a relationship between the first start moment and each of the process angle of the memory, the temperature of the memory, and the operating voltage of the memory.

In some embodiments, the driving circuit 600 is configured to amplify the voltage difference between the local data line LIO and the complementary local data line LIOB by driving a voltage on the local data line LIO upward and/or driving a voltage on the complementary local data line LIOB upward. A driving capability of driving the local data line LIO upward or driving the complementary local data line LIOB upward refers to a capability of driving the voltage on the local data line LIO or the complementary local data line LIOB to be raised, and may be measured based on a voltage change rate. The driving capability of driving the local data line LIO upward is negatively correlated with the voltage on the complementary local data line LIOB. The driving capability of driving the complementary local data line LIOB upward is negatively correlated with the voltage on the local data line LIO.

The voltage difference is generated between the local data line LIO and the complementary local data line LIOB, e.g., the voltage on the local data line LIO is greater than the voltage on the complementary local data line LIOB, that is, the voltage on the local data line LIO is large and the voltage on the complementary local data line LIOB is small. The driving capability of the driving circuit 600 in driving the complementary local data line LIOB upward is weak when the voltage on the local data line LIO is large. The driving capability of the driving circuit 600 in driving the local data line LIO upward is strong when the voltage on the complementary local data line LIOB is small. The voltage on the local data line LIO may be caused to be continuously greater than the voltage on the complementary local data line LIOB when the driving capability of the driving circuit 600 in driving the complementary local data line LIOB upward is weak and the driving capability of the driving circuit 600 in driving the local data line LIO upward is strong, thereby amplifying the voltage difference between the local data line LIO and the complementary local data line LIOB.

A principle of amplifying the voltage difference between the local data line LIO and the complementary local data line LIOB by the driving circuit 600 is described above with an example in which the voltage on the local data line LIO is greater than the voltage on the complementary local data line LIOB. A principle adopted when the voltage on the local data line LIO is less than the voltage on the complementary local data line LIOB is similar. Details are not described herein again.

In some embodiments, the driving circuit 600 includes a switch unit 630, a first driving unit 610, and a second driving unit 620. The switch unit 630 is connected to the first driving unit 610. The switch unit 630 is connected to the second driving unit 620. The first driving unit 610 is connected to the local data line LIO and the complementary local data line LIOB. The second driving unit 620 is connected to the local data line LIO and the complementary local data line LIOB.

Connection or disconnection between the first driving unit 610 and a first power supply terminal is controlled by the switch unit 630 under the control of a first control signal RdEnN. Connection or disconnection between the second driving unit 620 and the first power supply terminal is also controlled by the switch unit 630 under the control of the first control signal RdEnN. A voltage provided by the first power supply terminal is a power voltage VCC.

The voltage on the local data line LIO is driven upward by the first driving unit 610 based on the voltage on the complementary local data line LIOB when the first driving unit 610 is connected to the first power supply terminal. The voltage on the complementary local data line LIOB is driven upward by the second driving unit 620 based on the voltage on the local data line LIO when the second driving unit 620 is connected to the first power supply terminal.

A driving capability of the first driving unit 610 in driving the local data line LIO is negatively correlated with the voltage on the complementary local data line LIOB. A driving capability of the second driving unit 620 in driving the complementary local data line LIOB is negatively correlated with the voltage on the local data line LIO.

The first driving unit 610 and the second driving unit 620 are configured to amplify the voltage difference between the local data line LIO and the complementary local data line LIOB. The voltage difference is generated between the local data line LIO and the complementary local data line LIOB, e.g., the voltage on the local data line LIO is greater than the voltage on the complementary local data line LIOB, that is, the voltage on the local data line LIO is large and the voltage on the complementary local data line LIOB is small. The driving capability of the first driving unit 610 in driving the local data line LIO upward is strong when the voltage on the complementary local data line LIOB is small. The driving capability of the second driving unit 620 in driving the complementary local data line LIOB upward is weak when the voltage on the local data line LIO is large. The voltage on the local data line LIO may be caused to be continuously greater than the voltage on the complementary local data line LIOB when the driving capability of the first driving unit 610 in driving the local data line LIO upward is strong and the driving capability of the second driving unit 620 in driving the complementary local data line LIOB upward is weak, thereby amplifying the voltage difference between the local data line LIO and the complementary local data line LIOB.

A principle of amplifying the voltage difference between the local data line LIO and the complementary local data line LIOB by the first driving unit 610 and the second driving unit 620 is described above with an example in which the voltage on the local data line LIO is greater than the voltage on the complementary local data line LIOB. A principle adopted when the voltage on the local data line LIO is less than the voltage on the complementary local data line LIOB is similar. Details are not described herein again.

The switch unit 630 is configured to control the first driving unit 610 and the second driving unit 620 to amplify the voltage difference between the local data line LIO and the complementary local data line LIOB.

The voltage difference between the local data line LIO and the complementary local data line LIOB can be amplified by the first driving unit 610 and the second driving unit 620 when the switch unit 630 controls the first power supply terminal to be connected to the first driving unit 610 and controls the first power supply terminal to be connected to the second driving unit 620.

The voltage difference between the local data line LIO and the complementary local data line LIOB cannot be amplified by the first driving unit 610 and the second driving unit 620 when the switch unit 630 controls the first power supply terminal to be disconnected from the first driving unit 610 and controls the first power supply terminal to be disconnected from the second driving unit 620.

In some embodiments, the switch unit 630 controls, after the local data line LIO and the complementary local data line LIOB are charged to the precharge voltage, the first driving unit 610 to be connected to the first power supply terminal and controls the second driving unit 620 to be connected to the first power supply terminal, to prevent the equalizer circuit 500 from being unable to charge the local data line LIO and the complementary local data line LIOB to the precharge voltage because the first driving unit 610 and the second driving unit 620 are always connected to the first power supply terminal.

In the foregoing technical solution, the switch unit 630 is disposed to control connection between both of the first driving unit 610 and the second driving unit 620 and the first power supply terminal, to implement isolation between the first power supply terminal and a second power supply terminal, thereby preventing the equalizer circuit 500 from being unable to charge the voltages on the local data line LIO and the complementary local data line LIOB to the precharge voltage because the voltage difference between the local data line LIO and the complementary local data line LIOB is always amplified by the first driving unit 610 and the second driving unit 620, and avoiding a failure that accurate data transmission cannot be performed from the bit line BL to the local data line LIO.

In some embodiments, the first driving unit 610 includes a first P-type transistor P1. A source of the first P-type transistor P1 is connected to the switch unit 630. A drain of the first P-type transistor P1 is connected to the local data line LIO. A gate of the first P-type transistor P1 is connected to the complementary local data line LIOB.

The second driving unit 620 includes a second P-type transistor P2. A source of the second P-type transistor P2 is connected to the switch unit 630. A drain of the second P-type transistor P2 is connected to the complementary local data line LIOB. A gate of the second P-type transistor P2 is connected to the local data line LIO.

The switch unit 630 includes a third P-type transistor P3. A source of the third P-type transistor P3 is connected to the first power supply terminal. A drain of the third P-type transistor P3 is connected to the source of the first P-type transistor P1. The drain of the third P-type transistor P3 is further connected to the source of the second P-type transistor P2. The first control signal RdEnN is received by a gate of the third P-type transistor P3.

A lower gate voltage of a P-type transistor indicates a larger turn-on current of the P-type transistor, and a stronger capability of the P-type transistor in pulling up a voltage.

The third P-type transistor P3 is turned on, to control the source of the first P-type transistor P1 to be connected to the first power supply terminal, and control the source of the second P-type transistor P2 to be connected to the first power supply terminal. The voltage difference is generated between the local data line LIO and the complementary local data line LIOB, e.g., the voltage on the local data line LIO is greater than the voltage on the complementary local data line LIOB, that is, the voltage on the local data line LIO is large and the voltage on the complementary local data line LIOB is small. A driving capability of the first P-type transistor P1 in driving the local data line LIO upward is strong when the voltage on the complementary local data line LIOB is small. A driving capability of the second P-type transistor P2 in driving the complementary local data line LIOB upward is weak when the voltage on the local data line LIO is large. The voltage on the local data line LIO may be caused to be continuously greater than the voltage on the complementary local data line LIOB when the driving capability of the first P-type transistor P1 in driving the local data line LIO upward is strong and the driving capability of the second P-type transistor P2 in driving the complementary local data line LIOB upward is weak, thereby amplifying the voltage difference between the local data line LIO and the complementary local data line LIOB.

A principle of amplifying the voltage difference between the local data line LIO and the complementary local data line LIOB by the first P-type transistor P1 and the second P-type transistor P2 is described above with an example in which the voltage on the local data line LIO is greater than the voltage on the complementary local data line LIOB. A principle adopted when the voltage on the local data line LIO is less than the voltage on the complementary local data line LIOB is similar. Details are not described herein again.

In some embodiments, continuing to refer to FIG. 5, the driving circuit 600 further includes a first control circuit 700. A first output terminal of the first control circuit 700 is connected to a control terminal of the switch unit 630. A second output terminal of the first control circuit 700 is connected to a control terminal of the second-stage amplifier circuit 200. A mode signal CTRLPin is received by a first input terminal of the first control circuit 700. A reference signal RdEnPre is received by a second input terminal of the first control circuit 700. The first control circuit 700 is configured to generate the first control signal RdEnN based on the mode signal CTRLPin and the reference signal RdEnPre, and generate a second control signal RdEn based on the reference signal RdEnPre.

The driving circuit 600 is controlled by the first control signal RdEnN to amplify the voltage difference between the local data line LIO and the complementary local data line LIOB. The second-stage amplifier circuit 200 is controlled by the second control signal RdEn to amplify the voltage difference between the local data line LIO and the complementary local data line LIOB.

In some embodiments, the first control signal RdEnN is valid at a low level, and the second control signal RdEn is valid at a high level. The driving circuit 600 is controlled when the first control signal RdEnN is at the low level, to amplify the voltage difference between the local data line LIO and the complementary local data line LIOB. The second-stage amplifier circuit 200 is controlled when the second control signal RdEn is at the high level, to amplify the voltage difference between the local data line LIO and the complementary local data line LIOB.

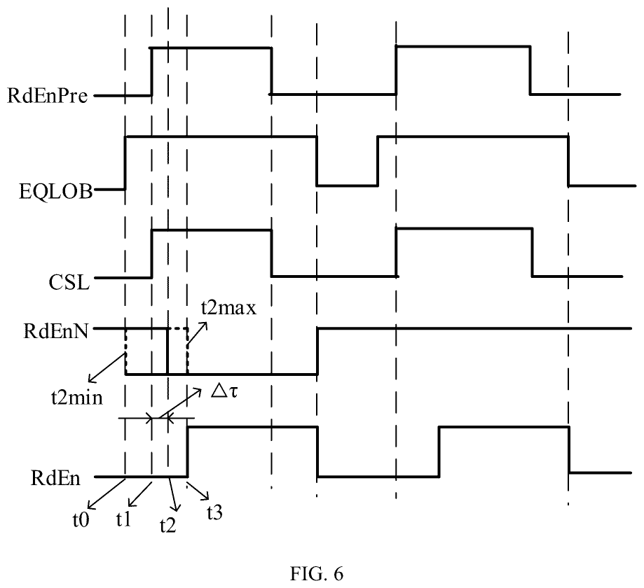

In some embodiments, as shown in FIG. 6, a start moment t2 at which the first control signal RdEnN is in a valid state is earlier than a start moment t3 at which the second control signal RdEn is in a valid state. The driving circuit 600 is first controlled to amplify the voltage difference between the local data line LIO and the complementary local data line LIOB. The second-stage amplifier circuit 200 is then controlled to amplify the voltage difference between the local data line LIO and the complementary local data line LIOB. Through such a disposition, the voltage difference between the local data line LIO and the complementary local data line LIOB is first amplified by the driving circuit 600, to compensate for the impact of the coupling capacitors on the voltages on the local data lines LIO. Then, the second-stage amplifier circuit 200 and the driving circuit 600 together amplify the voltage difference between the local data line LIO and the complementary local data line LIOB, and generate the voltage difference between the global data line GIO and the complementary global data line GIOB. Therefore, the time for amplifying the voltage difference between the local data line LIO and the complementary local data line LIOB by the second-stage amplifier circuit 200 is shortened, and performance of the timing parameter tCCD of the memory is improved.

In some embodiments, as shown in FIG. 6, the start moment t2 at which the first control signal RdEnN is in the valid state is later than an end moment t0 at which an equalization control signal EQLOB is in a valid state. The voltages on the local data line LIO and the complementary local data line LIOB are charged to a precharge voltage when the equalization control signal EQLOB is in the valid state.

In some embodiments, the equalization control signal EQLOB is a signal being valid at a low level, that is, the voltages on the local data line LIO and the complementary local data line LIOB are charged to the precharge voltage when the equalization control signal EQLOB is at the low level.

Through such a disposition, the driving circuit 600 and the second-stage amplifier circuit 200 are controlled after the voltages on the local data line LIO and the complementary local data line LIOB are charged to the precharge voltage, to amplify the voltage difference between the local data line LIO and the complementary local data line LIOB, to implement accurate data transmission between the bit line BL and the local data line LIO and between the complementary bit line BLB and the complementary local data line LIOB.

In some embodiments, the mode signal CTRLPin is configured to adjust the start moment t2 at which the first control signal RdEnN is in the valid state, that is, adjust the start moment at which the driving circuit 600 amplifies the voltage difference between the local data line LIO and the complementary local data line LIOB.

In some embodiments, a minimum value t2min of the start moment at which the first control signal RdEnN is in the valid state is the end moment at which the equalization control signal EQLOB is in the valid state. A maximum value t2max of the start moment at which the first control signal RdEnN is in the valid state is the start moment at which the second control signal RdEn is in the valid state.

In some embodiments, the first control circuit 700 is configured to determine a time step between the reference signal RdEnPre and the first control signal RdEnN based on the mode signal CTRLPin, and process the reference signal RdEnPre based on the time step to generate the first control signal RdEnN.

The time step may be a positive time step, and is marked as Δτ. The time step may alternatively be a negative time step, and is marked as−Δτ. The positive time step indicates that the start moment t2 at which the first control signal RdEnN is in the valid state is later than the start moment t1 at which the reference signal RdEnPre is in the valid state, and there is a difference Δτ between t1 and t2. The negative time step indicates that the start moment t2 at which the first control signal RdEnN is in the valid state is earlier than the start moment t1 at which the reference signal RdEnPre is in the valid state, and there is a difference Δτ between t1 and t2.

The mode signal CTRLPin is determined based on any one or more parameters of a first time interval, a process angle of the memory, a temperature of the memory, and an operating voltage of the memory. The first time interval is a time interval between adjacent row addressing and column addressing of the memory.

In some embodiments, the mode signal CTRLPin is determined based on the first time interval. A shorter first time interval indicates a larger time step corresponding to the mode signal CTRLPin, and a later start moment at which the first control signal RdEnN is in the valid state.

A smaller absolute value of the negative time step −Δτ indicates a larger negative time step when the time step is the negative time step −Δτ. A larger absolute value of the positive time step At indicates a larger positive time step when the time step is the positive time step Δτ.

In some embodiments, the mode signal CTRLPin is determined based on any one or more parameters of a process angle of the memory, a temperature of the memory, and an operating voltage of the memory. Multiple tests may be performed on the memory to determine a relationship between the start moment at which the first control signal RdEnN is in the valid state and each of the process angle of the memory, the temperature of the memory, and the operating voltage of the memory, to reduce the noise introduced to the bit line BL and the complementary bit line BLB.

Through such a disposition, the start moment at which the driving circuit 600 amplifies the voltage difference between the local data line LIO and the complementary local data line LIOB is adjusted when the timing parameter of the memory is poor, to reduce the noise introduced by the local data line LIO and the complementary local data line LIOB to the bit line BL and the complementary bit line BLB, and implement accurate data transmission.

In some embodiments, the reference signal RdEnPre is a column selection signal CSL. Connection or disconnection between the bit line BL and the local data line LIO and connection or disconnection between the complementary bit line BLB and the complementary local data line LIOB are controlled by the second control circuit 400 under the control of the column selection signal CSL.

In some embodiments, the reference signal RdEnPre is not limited to the column selection signal CSL, and may be any other signal, provided that the first control signal RdEnN meets the foregoing timing relationship. This is not limited herein.

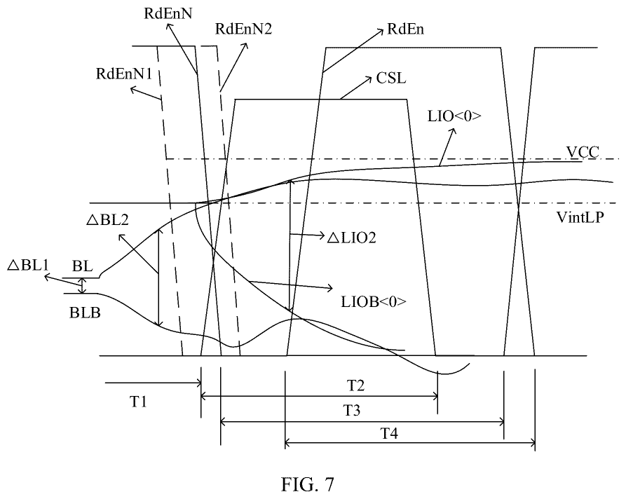

An operating principle of the memory described in this embodiment of the present disclosure is described below with reference to FIG. 7.

In a phase T1, the column selection signal CSL is at a low level, the bit line BL is disconnected from the local data line LIO, and the complementary bit line BLB is disconnected from the complementary local data line LIOB. Data “1” is stored in the storage cell. Charge sharing is performed between the storage cell and the bit line BL. In this case, a small voltage difference ΔBL1 is generated between the bit line BL and the complementary bit line BLB. The small voltage difference ABL1 between the bit line BL and the complementary bit line BLB is amplified by the first-stage amplifier circuit 100 in the phase T1, e.g., amplified to a voltage difference ΔBL2.

In a phase T2, the column selection signal CSL is at a high level, the bit line BL is connected to the local data line LIO, and the complementary bit line BLB is connected to the complementary local data line LIOB. Data on the bit line BL and the complementary bit line BLB is transmitted to the local data line LIO and the complementary local data line LIOB. In this case, a voltage on a middle local data line LIO<0> is affected by local data lines LIO<2> and LIO<3> on two sides due to a coupling capacitor if voltage jump occurs on the local data lines LIO<2> and LIO<3> on the two sides because data “0” is transmitted, but the data “1” is transmitted on the middle local data line LIO<1>, that is, the voltage on the middle local data line LIO is close to the precharge voltage VintLP.

In a phase T3, the first control signal RdEnN is at the low level, and the third P-type transistor P3 is turned on. The voltage on the local data line LIO is driven upward by the first P-type transistor P1. The voltage on the complementary local data line LIOB is driven upward by the second P-type transistor P2. The driving capability of the first P-type transistor P1 in pulling up the local data line LIO is better than the driving capability of the second P-type transistor P2 in pulling up the complementary local data line LIOB. In this way, an impact of the local data lines LIO<2> and LIO<3> on the two sides on the middle local data line LIO<0> is compensated for. In this case, the voltage on the complementary local data line LIOB is driven downward by the complementary bit line BLB, to compensate for the impact of the local data lines LIO<2> and LIO<3> on the two sides on a voltage on the middle local data line LIO<0>, and amplify the voltage difference between the local data line LIO and the complementary local data line LIOB.

In a phase T4, the second control signal RdEn is at the high level. The second-stage amplifier circuit 200 starts to amplify the voltage difference between the local data line LIO and the complementary local data line LIOB. In this case, the voltage difference ΔLIO2 is already large because the voltage difference between the local data line LIO and the complementary local data line LIOB is already amplified by the driving circuit 600. The second-stage amplifier circuit 200 and the driving circuit 600 together amplify the voltage difference between the local data line LIO and the complementary local data line LIOB. Therefore, the time for amplifying the voltage difference between the local data line LIO and the complementary local data line LIOB by the second-stage amplifier circuit 200 can be shortened.

In FIG. 7, an example in which the data “1” is stored in the storage cell is used for description. A case in which the data “0” is stored in the storage cell is similar to the case in which the data “1” is stored in the storage cell. Details are not described herein again.

Continuing to refer to FIG. 7, the start moment at which the first control signal RdEnN is in the valid state may be adjusted between a start moment indicated by RdEnN1 and a start moment indicated by RdEnN2, to adjust a size of the noise introduced by the local data line LIO and the complementary local data line LIOB to the bit line BL and the complementary bit line BLB.

A person skilled in the art can easily figure out other implementation solutions of the present disclosure after considering the specification and practice of the present disclosure herein. The present disclosure aims to cover any variations, uses, or adaptations of the present disclosure. These variations, uses, or adaptations follow the general principles of the present disclosure and include common knowledge or conventional technical means in the art that are not disclosed in the present disclosure. The specification and embodiments are merely considered as examples, and the true scope and spirit of the present disclosure are pointed out in the following claims. It should be understood that the present disclosure is not limited to the precise structures described above and shown in the accompanying drawings, and various modifications and changes may be made without departing from the scope thereof. The scope of the present disclosure is limited only by the appended claims.

What is claimed is:

1. A memory, comprising:
a first-stage amplifier circuit, connected to a bit line and a complementary bit line, and configured to amplify a voltage difference between the bit line and the complementary bit line;
a second-stage amplifier circuit, connected to a local data line and a complementary local data line, further connected to a global data line and a complementary global data line, amplifying a voltage difference between the local data line and the complementary local data line after the local data line is connected to the bit line and the complementary local data line is connected to the complementary bit line, and generating a voltage difference between the global data line and the complementary global data line; and
a driving circuit, connected to the local data line and the complementary local data line, and amplifying the voltage difference between the local data line and the complementary local data line.

2. The memory according to claim 1, wherein the memory further comprises:
an equalizer circuit, connected to the local data line and the complementary local data line, and charging voltages on the local data line and the complementary local data line to a precharge voltage before the local data line is connected to the bit line and the complementary local data line is connected to the complementary bit line; and
the driving circuit is configured to amplify the voltage difference between the local data line and the complementary local data line after the voltages on the local data line and the complementary local data line are charged to the precharge voltage.

3. The memory according to claim 1, wherein a start moment at which the driving circuit amplifies the voltage difference between the local data line and the complementary local data line is earlier than a start moment at which the second-stage amplifier circuit amplifies the voltage difference between the local data line and the complementary local data line.

4. The memory according to claim 1, wherein
a first start moment is in a first value range when a first time interval is in a first time range;
the first start moment is in a second value range when the first time interval is in a second time range;
the first time interval is a time interval between adjacent row addressing and column addressing of the memory, and the first start moment is a start moment at which the driving circuit amplifies the voltage difference between the local data line and the complementary local data line; and
an upper limit value of the first time range is less than or equal to a lower limit value of the second time range, and an upper limit value of the first value range is greater than or equal to a lower limit value of the second value range.

5. The memory according to claim 1, wherein the driving circuit is configured to:
amplify the voltage difference between the local data line and the complementary local data line by driving a voltage on the local data line and/or a voltage on the complementary local data line upward; and
a driving capability of driving the local data line upward is negatively correlated with the voltage on the complementary local data line, and a driving capability of driving the complementary local data line upward is negatively correlated with the voltage on the local data line.

6. The memory according to claim 5, wherein the driving circuit comprises:
a switch unit, connected to a first driving unit and a second driving unit, controlling connection or disconnection between the first driving unit and a first power supply terminal under the control of a first control signal, and controlling connection or disconnection between the second driving unit and the first power supply terminal under the control of the first control signal, the first power supply terminal providing a power voltage;
the first driving unit, connected to the local data line and the complementary local data line, and driving the voltage on the local data line upward based on the voltage on the complementary local data line when the first driving unit is connected to the first power supply terminal; and
the second driving unit, connected to the local data line and the complementary local data line, and driving the voltage on the complementary local data line upward based on the voltage on the local data line when the second driving unit is connected to the first power supply terminal; and
a driving capability of the first driving unit in driving the local data line is negatively correlated with the voltage on the complementary local data line, and a driving capability of the second driving unit in driving the complementary local data line is negatively correlated with the voltage on the local data line.

7. The memory according to claim 6, wherein
the first driving unit comprises:
a first P-type transistor, a source being connected to the switch unit, a drain being connected to the local data line, and a gate being connected to the complementary local data line; and
the second driving unit comprises:
a second P-type transistor, a source being connected to the switch unit, a drain being connected to the complementary local data line, and a gate being connected to the local data line.

8. The memory according to claim 7, wherein the switch unit comprises:
a third P-type transistor, a source being connected to the first power supply terminal, a drain being connected to the source of the first P-type transistor, the drain being further connected to the source of the second P-type transistor, and a gate receiving the first control signal.

9. The memory according to claim 6, wherein the driving circuit further comprises:
a first control circuit, a first output terminal being connected to a control terminal of the switch unit, a second output terminal being connected to a control terminal of the second-stage amplifier circuit, and a first input terminal receiving a mode signal and a second input terminal receiving a reference signal to generate the first control signal based on the mode signal and the reference signal and generate a second control signal based on the reference signal; and
a start moment at which the first control signal is in a valid state is earlier than a start moment at which the second control signal is in a valid state, and the second-stage amplifier circuit is controlled by the second control signal to amplify the voltage difference between the local data line and the complementary local data line.

10. The memory according to claim 9, wherein the start moment at which the first control signal is in the valid state is later than an end moment at which an equalization control signal is in a valid state, and the voltages on the local data line and the complementary local data line are charged to a precharge voltage when the equalization control signal is in the valid state.

11. The memory according to claim 9, wherein the control circuit is configured to:
determine a time step between the reference signal and the first control signal based on the mode signal; and
process the reference signal based on the time step to generate the first control signal.

12. The memory according to claim 11, wherein the mode signal is determined based on any one or more parameters of a first time interval, a process angle of the memory, a temperature of the memory, and an operating voltage of the memory; and
the first time interval is a time interval between adjacent row addressing and column addressing of the memory.

13. The memory according to claim 9, wherein the reference signal is a column selection signal, and the column selection signal is configured to control connection or disconnection between the bit line and the local data line, and is further configured to control connection or disconnection between the complementary bit line and the complementary local data line.

14. The memory according to claim 1, wherein the memory further comprises:
a second control circuit, connected to the bit line and the complementary bit line, further connected to the local data line and the complementary local data line, and configured to receive a column selection signal, control connection or disconnection between the bit line and the local data line under the control of the column selection signal, and control connection or disconnection between the complementary bit line and the complementary local data line under the control of the column selection signal.

15. The memory according to claim 1, wherein the memory further comprises:
a third-stage amplifier circuit, connected to the global data line and the complementary global data line, and configured to amplify the voltage difference between the global data line and the complementary global data line.
